(19) United States
(12) Patent Application Publication
(10) Pub. No.: US 2007/0158723 A1
(43) Pub. Date: Jul. 12, 2007

(54) SEMICONDUCTOR STORAGE DEVICE WITH IMPROVED DEGREE OF MEMORY CELL INTEGRATION AND METHOD OF MANUFACTURING THEREOF

(75) Inventor: Naoki YOKOI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/620,130

(22) Filed: Jan. 5, 2007

(30) Foreign Application Priority Data
Jan. 12, 2006 (JP) 2006-004819

(51) Int. Cl. H01L 29/94

(52) U.S. Cl. 257/298

(57) ABSTRACT

A semiconductor storage device of the present invention has a configuration in which a plurality of memory cells respectively including a transistor connected to a storage element for accumulating data are used, a bit line and a word line for specifying one of a plurality of memory cells are used. A structure in which a source electrode and a drain electrode hold an active region is formed vertically to a substrate face. The same bit line is connected to the first two-memory cell unit adjacently formed in a predetermined direction. The same word line is formed, which is a gate electrode of the transistors of the second two-memory cell unit which includes one memory cell of the first two-memory cell unit and which is adjacently formed in the predetermined direction.

This application is based upon and claims the benefit of priority from Japanese Patent Application No. 2006-4819 filed on Jan. 12, 2006, the content of which is incorporated by reference.

### BACKGROUND OF THE INVENTION

1. Field of the Invention

The present invention relates to a semiconductor storage device having a plurality of storage elements for accumulating data and a method of manufacturing thereof.

2. Description of the Related Art

In the case of conventional semiconductor storage device, a DRAM (Dynamic Random Access Memory) uses a memory cell structure made up of one MOS (Metal Oxide Semiconductor) transistor and one capacitor (Japanese Patent Laid-Open No. S61-176148).

The configuration of a conventional DRAM is described below. FIG. 1A is a top layout view showing a memory cell array and FIG. 1B is a sectional schematic view taken along line A-A′in FIG. 1A.

As shown in FIG. 1A, memory cell arrays are divided into 2-bit cell units 102 that serve as the region for memory cells having 2 bits. As shown in FIG. 1B, in 2-bit cell unit 102 which is held between element separation regions, two MOS transistors are formed on the surface of silicon substrate 1. The MOS transistor has n-type diffusion region 103 which is a region in which n-type conductive impurities are diffused, p-type active region 104 in which a channel is formed, and gate electrode 112 formed on gate insulating film 111. The MOS transistor is an n-type MOS transistor because n-type diffusion region 103 serves as the source and drain regions.

Moreover, one of two n-type diffusion regions 103 is connected to bit line 121 through contact plug 132 and the other is connected to a capacitor (not shown) through contact plug 131. Contact plug 132 is shared by two MOS transistors in the same 2-bit cell units 102 arranged in a direction parallel with a bit line. And, a conventional memory cell uses a planar MOS transistor in which source-drain current flows in a direction parallel with bit line 121 when a MOS transistor is turned on.

Moreover, gate electrode 112 serving as a word line is set in a direction vertical to the bit line to constitute a plurality of MOS transistors which can be driven by one word line segment in order to decrease the number of word lines as much as possible and to improve the degree of memory cell integration. In FIG. 1A, it is possible to simultaneously drive a plurality of MOS transistors arranged along gate electrode 112 serving as one word line segment in each of 2-bit cell units 2 under different bit lines.

By selecting one of the above bit lines and one of the above word lines, it is possible to drive a predetermined MOS transistor and to charge or discharge a capacitor connected to the MOS transistor.

In the case of a memory cell of a conventional DRAM, a word line serving as a gate electrode is set to each of two MOS transistors in a 2-bit cell unit arranged in a direction parallel with a bit line. This is because the MOS transistor is a planar type and it is impossible for two MOS transistors to share a single word line, and thus a word line is provided for each of the two MOS transistors. In this case, a word line is required for each of the MOS transistors that are set along a bit line, and any improvement to the amount of memory cell integration is limited.

### SUMMARY OF THE INVENTION

It is an object of the present invention to provide semiconductor storage device with improved the degree of memory cell integration and a method of manufacturing thereof.

According to the present invention, semiconductor storage device comprises a plurality of memory cells respectively including a transistor connected to a storage element for accumulating data, and a bit line and a word line for specifying one of the plurality of memory cells, wherein in the case of the transistor, a structure in which a source electrode and a drain electrode hold an active region is formed vertically to a substrate face, the same bit line is connected to the first two-memory cell unit adjacently formed in a predetermined direction, and the same word line is formed, which is a gate electrode of the transistors of the second two-memory cell unit which includes one memory cell of the first two-memory cell unit and which is adjacently formed in the predetermined direction.

In the case of the present invention, because a tandem structure is applied to a transistor and one word line is shared by two memory cells, it is possible to simultaneously drive two MOS transistors by one word line. More than before, it is possible to decrease the number of word lines for the entire memory cell array. As a result, the area that one memory cell occupies is decreased and the degree of memory cell integration is improved in accordance with the design rule just as before.

The above and other objects, features and advantages of the present invention will become apparent from the following description with reference to the accompanying drawings which illustrate examples of the present invention.

### BRIEF DESCRIPTION OF THE DRAWINGS

FIGS. 1A and 1B are a planar layout diagram and sectional schematic view respectively showing the memory cell array of a conventional DRAM;

FIGS. 2A and 2B are a planar layout diagram and sectional schematic view respectively showing the memory cell array of the semiconductor storage device of Embodiment 1;

FIGS. 3A and 3B are a top view and a sectional view respectively for explaining operations of the semiconductor storage device of Embodiment 1;

FIGS. 4A to 4L are sectional schematic views showing a method of manufacturing the semiconductor storage device of Embodiment 1; and

FIGS. 5A and 5B are a planar layout diagram and sectional schematic view respectively showing the memory cell array of the semiconductor storage device of Embodiment 2.

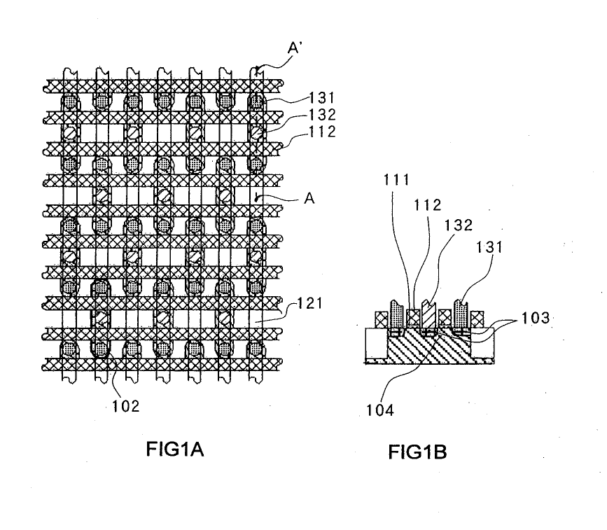

### DETAILED DESCRIPTION OF THE PREFERRED EMBODIMENTS

A semiconductor storage device of the present invention has a configuration in which MOS transistors of two adjacent memory cells share one word line by using a tandem MOS transistor as a selecting transistor. The following embodiment is described by using a case in which a semiconductor storage device is a DRAM.

### Embodiment 1

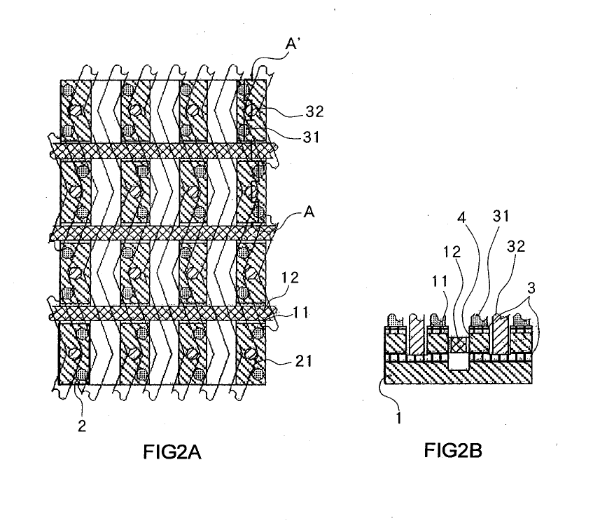

The configuration of semiconductor storage device of this embodiment is described below. FIG. 2A is a planar layout diagram showing a memory cell array and FIG. 2B is a sectional schematic view taken along line A-A′ in FIG. 2A.

As shown in FIG. 2A, in the case of a memory cell, memory cell regions are divided into 2-bit cell units 2. As shown in FIG. 2B, two square-polar MOS transistors are set on silicon substrate 1 in 2-bit cell unit 2. The MOS transistor has n-type diffusion region 3 set to the top end and bottom end of a square pole and p-type active region 4 which is held between two n-type diffusion regions 3 and which is formed at the central portion of the square pole. In the case of the MOS transistor, because the source and drain are formed of an n-type impurity diffusion layer, the MOS transistor is an n-type MOS transistor.

Moreover, gate insulating film 11 is formed at the laterals of the square pole and gate electrode 12 is formed by making contact with gate insulating film 11. The distance between two n-type diffusion regions 3 serves as a gate length. Gate electrode 12 is shared by two adjacent MOS transistors. Gate electrode 12 serves as a word line for selecting a predetermined MOS transistor from MOS transistors arranged as an array.

N-type diffusion region 3 at the bottom end is connected to bit line 21 through contact plug 31. Contact plug 31 and bit line 21 are shared by two adjacent MOS transistors in the same 2-bit cell unit 2. By observing one MOS transistor, it can be seen that MOS transistors that share gate electrode 12 are different from MOS transistors that share bit line 21. Contact plug 31 connected to a capacitor (not shown) is connected to n-type diffusion region 3 at the top end.

According to the structure and arrangement of the memory cells, MOS transistors which are formed at the lateral side of two-line adjacent memory cell regions are simultaneously driven by one gate electrode. Therefore, it is possible to increase the number of memory cells which can be arranged in a unit area to a greater degree than before and the degree of memory cell integration is improved.

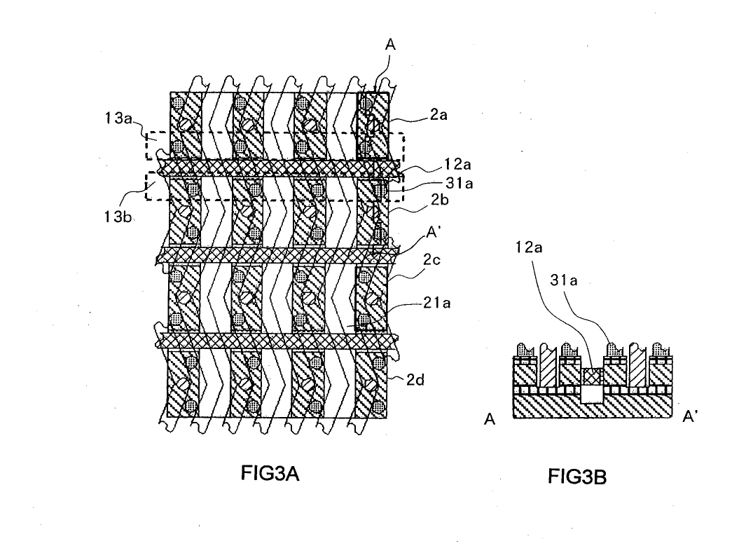

Next, operations of the semiconductor storage device of this embodiment are described. FIGS. 3A and 3B are illustrations for explaining operations.

FIG. 3A is a planar layout diagram showing a memory cell array and FIG. 3B is a sectional schematic view taken along line A-A′ in FIG. 3A. In this case, it is assumed that the number of cells of a memory cell array is set to 4×8 in FIG. 3A. Moreover, word lines at the top end and bottom end of a memory cell array are omitted.

When applying a gate voltage to one word line 12a among a plurality of word lines, two-line MOS transistors included in areas 13a and 13b are all turned on with word line 12a acting as a gate electrode. Four MOS transistors are present in each line. Then, when applying a voltage to one bit line 21a among a plurality of bit lines, a voltage is applied between sources and drains of four MOS transistors set to bit cell regions 2b and 2d.

In this case, a MOS transistor, in which voltage is applied to a gate electrode and in which voltage is applied between the source and drain electrodes, is just a MOS transistor that is located at the line of area 13b of 2-bit cell unit 2b. In the case of the MOS transistor, current flows in a direction vertical to the surface of silicon substrate 1 between source and drain. Then, charging/discharging of a capacitor (not shown) connected to contact plug 31a is performed through bit line 21a. Thereby, it is possible to write and read data in or from the capacitor of a predetermined memory cell.

As described above, by selecting one word line and one bit line and applying a voltage to them, it is possible to charge and discharge one capacitor that has been selected as the only capacitor for charging/discharging. The operation of selecting a word line and a bit line in order to charge and discharge a predetermined capacitor is the same for a conventional DRAM.

However, in the case of this embodiment, by applying a gate voltage to one word line, it is possible to simultaneously turn on transistors by setting two lines. Therefore, the advantages are that the area that one memory cell occupies is decreased and the degree of memory cell integration is improved in accordance with the design rule the same as before.

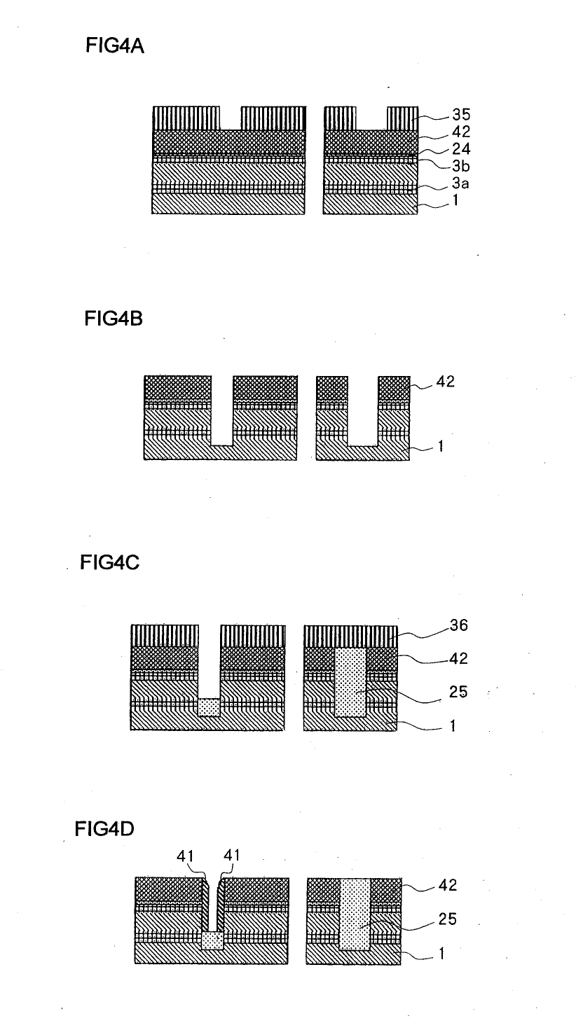

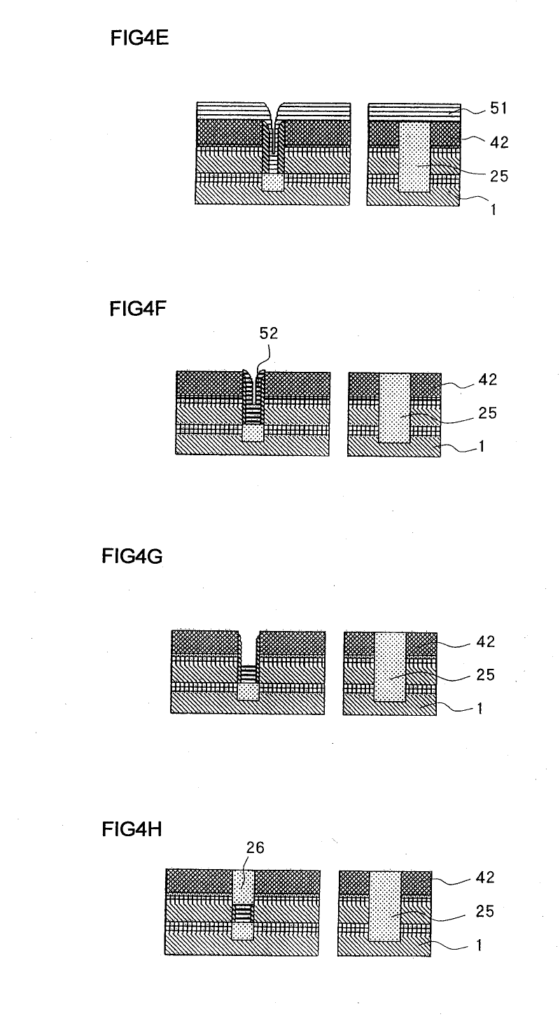

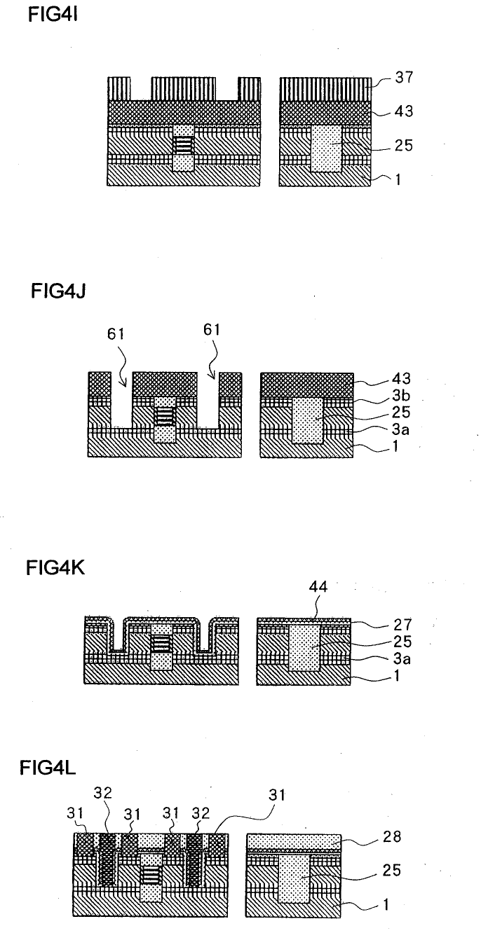

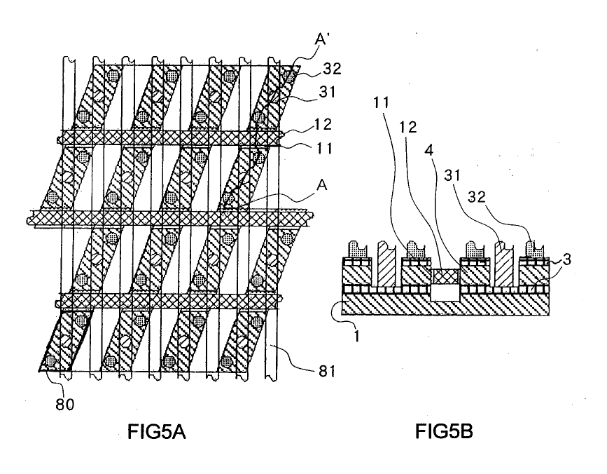

Next, a method of manufacturing the semiconductor storage device of this embodiment is described below. FIGS. 4A to 4L are sectional schematic views showing the method of manufacturing semiconductor storage device of this embodiment. In each drawing, the left side shows a cross section in the direction vertical to the longitudinal direction of the pattern of a gate electrode in a memory cell array and the right side shows a cross section in the direction parallel with the longitudinal direction of the pattern of the gate electrode.

Oxide film 24 having a thickness of approx. 10 nm is first formed by thermally oxidizing the surface of p-type silicon substrate 1 and then n-type impurities such as arsenic are ion-implanted to form n-type diffusion regions 3a and 3b that serve as source and drain regions between which a silicon layer is sandwiched. In this case, when ion-implanting n-type impurities into silicon substrate 1, two impurity diffusion regions in which the depths from the surface of silicon substrate 1 are different are formed as described above by changing the acceleration energy or ion type. Then, a silicon layer held by n-type diffusion regions 3a and 3b becomes p-type active region 4. Next, first silicon nitride film 42 having a thickness of approx. 100 nm is deposited through the chemical vapor deposition (CVD) process, and first photoresist pattern 35 is formed by photolithography on first silicon nitride film 42 (FIG. 4A).

Then, dry etching is applied to first silicon nitride film 42 by using first photoresist pattern 35 as a mask. Moreover, after removing first photoresist pattern 35 by ashing or the like, dry etching is applied to silicon substrate 1 up to a depth of approx. 300 nm by using first silicon nitride film 42 as a mask to form a groove-like pattern on silicon substrate 1 (FIG. 4B). In this case, the groove-like pattern passes through n-type diffusion region 3a.

Then, first silicon oxide film 25 is deposited by CVD process and next, first silicon oxide film 25 formed on first silicon nitride film 42 is removed by the chemical and mechanical polishing (CMP) process, and second photoresist pattern 36 is formed on first silicon nitride film 42. Then, dry etching is applied to first silicon oxide film 25 only at a groove portion on which a gate electrode is formed, by using second photoresist pattern 36 as a mask to leave first silicon oxide film 25 with a thickness of approx. 100 nm at the bottom of the groove (FIG. 4C). In this case, as shown at the left side of FIG. 4C, the height of the top end of first silicon oxide film 25 is adjusted to the height of the top side of n-type diffusion region 3a.

After removing second photoresist pattern 36, a gate insulating film (not shown in a drawing because the film is very thin) is formed by applying thermal oxidation to silicon substrate 1, and polysilicon film 41 doped with phosphor is deposited on the gate insulating film by the CVD process. By applying dry etching to polysilicon film 41, a side wall is formed as shown in FIG. 4D.

Moreover, as shown in FIG. 4E, cobalt film 51 having a thickness of approx. 120 nm is deposited by the sputtering process.

Thereafter, cobalt silicide 52 is formed by making cobalt film 51 react with polysilicon film 41 by RTA (Rapid Thermal Annealing) at a temperature of approx. 700° C. Then, unreacted cobalt film 51 is removed (FIG. 4F) by an acidic drug solution such as a mixed solution of hydrochloric acid, hydrogen peroxide and deionized water (for example, the mixture ratio of hydrochloric acid:hydrogen peroxide:deionized water is 1:1:5 and solution temperature is approx. 70° C.).

Then, as shown in FIG. 4G, extra cobalt silicide 52 is removed by a chemical containing hydrogen fluoride (HF) and then cobalt silicide 52 is crystallized by performing RTA at a temperature of approx. 800° C. again. In this case, the height of the top end of cobalt silicide 52 is set so as to be so that the height of the top end of cobalt silicide 52 is adjusted to the height of the down side of n-type diffusion region 3b. Then, second silicon oxide film 26 is deposited by the CVD process and then, extra second silicon oxide film 26 formed on first silicon nitride film 42 is removed by the CMP process (FIG. 4H). Thereafter, first silicon nitride film 42 is removed by wet etching with phosphoric acid at 160° C. and then second silicon nitride film 43 is deposited by the CVD process. Then, third photoresist pattern 37 is formed on second silicon nitride film 43 (FIG. 4I).

Next, dry etching is applied to second silicon nitride film 43 by using third photoresist pattern 37 as a mask. After removing third photoresist pattern 37 by ashing or the like, dry etching is applied to silicon substrate 1 by using second silicon nitride film 43 as a mask to form opening 61 that penetrates several layers to the top end of n-type diffusion region 3a (FIG. 4J).

Then, after removing second silicon nitride film 43 by wet etching with phosphoric acid at 160° C., third silicon oxide film 27 and third silicon nitride film 44 are deposited in order by the CVD process. Then, fourth silicon oxide film 28 serving as an inter-layer film is deposited on third silicon nitride film 44. Thereafter, openings that penetrate several layers to the top side of n-type diffusion regions 3a and 3b respectively is formed by the same method as before and then, contact plug 32 that is to be connected to a bit line and contact plug 31 that is to be connected to a capacitor are formed (FIG. 4L), and a bit line (not shown), a capacitor (not shown), and an aluminum wiring (not shown) are formed sequentially.

According to this embodiment of the method of manufacturing the semiconductor storage device, a plurality of tandem-structure MOS transistors sharing one word line are simultaneously formed.

Other than processes that use phosphoric acid at 160° C., another processes can be used to remove silicon nitride film. Moreover, in the case of this embodiment, the height of the bottom end of cobalt silicide 52 is adjusted to the height of the top side of n-type diffusion region 3a and the height of the top end of cobalt silicide 52 is adjusted to the height of the down side of n-type diffusion region 3b. However, each position may also be shifted to correspond to the target characteristic of a transistor. For example, by overlapping cobalt silicide 52 on n-type diffusion regions 3a and 3b, the driving speed of a transistor is further increased. Moreover, by using an offset structure in which cobalt silicide 52 does not come into contact with n-type diffusion regions 3a and 3b, the off leak current of a transistor is decreased.

### Embodiment 2

In the case of Embodiment 1, the planar shape of a memory cell is square and a cross section parallel with the substrate surface is rectangular in the p-type active region of a MOS transistor that corresponds to the shape of the memory cell. However, in the case of semiconductor storage device of this embodiment, the planar shape of a memory cell is a parallelogram and accordingly a cross section parallel with a substrate surface is a parallelogram in the p-type active region.

The configuration of the semiconductor storage device of this embodiment is described below. FIG. 5A is a planar layout diagram showing a memory cell array and FIG. 5B is a sectional schematic view taken along the line A-A′ in FIG. 5A.

As shown in FIG. 5A, the planar shape of 2-bit cell unit 80 is a parallelogram and the planar shape of memory cell for 1 bit is also a parallelogram. Accordingly, shapes of cross sections that are parallel with the substrate surface in n-type diffusion region 3 and p-type active region 4 also respectively are a parallelogram. However, the shape of the cross section taken along line A-A′ in FIG. 5A is the same as in the case of Embodiment 1. Therefore, the method for driving a MOS transistor and charging/discharging a capacitor is the same as in the case of Embodiment 1 and its detailed description is omitted here.

Moreover, as shown in FIG. 5A, the planar shape of bit line 81 is linear.

By forming the planar shape of a memory cell into a parallelogram, it is possible to connect contact plugs 31, that are to be connected, to the same bit line by a straight line. In the case of Embodiment 1, the planar shape of a bit line is corrugated. However, the planar shape of bit line 81 of this embodiment is linear. Thereby; there is the advantage that a bit line is easily patterned.

Moreover, in the case of this embodiment, a silicon substrate whose the plane direction of the surface is (110) surface according to the Miller indices is used so that each pattern lateral side of a memory cell region becomes a plane direction equivalent to (111) surface. In this case, Si (111) surface can be easily flattened by wet etching using ammonia or the like. Therefore, variations of shapes of n-type diffusion region 3 and p-type active region 4 become smaller than before. As a result, advantages are obtained in which it is possible to stably form the shape of each MOS transistor, and variation of the characteristics of a MOS transistor in a substrate is decreased.

Embodiments 1 and 2 are described as concerns the case of DRAM. However, the present invention can be applied to the semiconductor storage device of PRAM (phase change RAM) or FeRAM (ferroelectric RAM).

While preferred embodiments of the present invention have been described using specific terms, such description is for illustrative purposes only, and it is to be understood that changes and variations may be made without departing from the spirit or scope of the following claims.

What is claimed is:

1. A semiconductor storage device comprising a plurality of memory cells respectively including a transistor connected to a storage element for accumulating data, and a bit line and a word line for specifying one of said plurality of memory cells, wherein
in a case of said transistor, a structure in which a source electrode and a drain electrode hold an active region is formed vertically to a substrate face,
same said bit line is connected to a first two-memory cell unit adjacently formed in a predetermined direction, and
same said word line is formed, which is a gate electrode of said transistors of a second two-memory cell unit which includes one memory cell of said first two-memory cell unit and which is adjacently formed in said predetermined direction.

2. The semiconductor storage device according to claim 1, wherein each of planar shapes of said plurality of memory cells is a parallelogram.

3. The semiconductor storage device according to claim 2, wherein a plane direction of said substrate face is (110) surface according to Miller indices, and
a pattern lateral of each region of said plurality memory cells respectively is a plane direction equivalent to (111) surface.

4. A method of manufacturing semiconductor storage device comprising the steps of:
forming a first conductive impurity diffusion region, having a different conductivity from a substrate, at a predetermined depth from a surface of said substrate, and forming a second impurity diffusion region which is separated from a top end of said first impurity diffusion region on said surface of said substrate by a predetermined distance and which has the same conductivity as that of said first impurity diffusion region;
forming a first opening passing through said first and second impurity diffusion regions and a region between these impurity regions from said surface of said substrate;
embedding a first insulating film up to a height of a top end of said first impurity diffusion region in said first opening and separating said first impurity diffusion region;
forming a second insulating film on a side wall of said first opening in which said first insulating film is embedded partway;
embedding a conductive film up to a height of a bottom end of said second impurity diffusion region in said first opening on which said second insulating film is formed on said side wall to form a gate electrode;
embedding a third insulating film up to said surface of said substrate on said first opening in which said gate electrode is formed to separate said second impurity diffusion region;
forming two second openings which reach said first impurity diffusion region and which are set at symmetric positions by using said gate electrode as a central axis and in which a side wall is covered with an insulating film;
forming two third openings which reach said second impurity diffusion region and which are set at symmetric positions by using said gate electrode as a central axis and which are set between said second opening and said gate electrode respectively; and
embedding a conductive film in said second and third opening to form a contact plug.
